(19) United States
(12) Patent Application Publication
(10) Pub. No.: US 2026/0050016 A1
(43) Pub. Date: Feb. 19, 2026

(54) Sample Accurate Waveform Measurement Synchronization

(71) Applicant: NATIONAL INSTRUMENTS CORPORATION, Austin, TX (US)

(72) Inventors: Jordan Greenstreet, Leander, TX (US); Eric Hartner, Apex, NC (US)

(21) Appl. No.: 19/301,171

(22) Filed: Aug. 15, 2025

Related U.S. Application Data
(60) Provisional application No. 63/683,834, filed on Aug. 16, 2024.

(51) Int. Cl. G01R 19/25; G01R 13/02; G01R 31/28

(52) U.S. Cl. CPC G01R 19/2509; G01R 13/0272; G01R 31/2822

(57) ABSTRACT

In some embodiments, a method for synchronizing radio frequency (RF) devices can include receiving, a first stimuli signal including a maker signal from a first RF device and an output signal from a second RF device, wherein the output signal can be based at least in part on a second stimuli signal including a pulse waveform transmitted from the first RF device to the second RF device. The method can include digitizing the pulse waveform, measuring delay values between a first sample of the first stimuli signal and the digitized pulse waveform, and adjusting a timing of the marker signal. The method can include performing one or more pulse delay measurements associated with the first stimuli signal and the output signal as well as calculating a trigger delay. The method can also include performing, using the trigger delay, one or more measurements associated with a device under test (DUT).

### PRIORITY CLAIM

This application claims benefit of priority to provisional application No. 63/683,834 entitled “Sample Accurate Waveform Measurement Synchronization”, filed on Aug. 16, 2024, whose disclosure is hereby incorporated by reference in its entirety as though fully and completely set forth herein.

### FIELD OF THE INVENTION

The present invention relates to the field of high-speed pulse measurement and involves systems and methods for sample accurate waveform measurement synchronization.

### DESCRIPTION OF THE RELATED ART

As high-speed pulse measurements play a major role in testing a variety of electronics in order to assess electrical responses to various electrical stimuli, significant attention has been given to synchronization techniques to utilize in order to perform more accurate measurements with smaller margins of error.

For example, in some instances, the timing relationship between a signal generator and the oscilloscope can be unknown to the user. According to some scenarios, if the rising edge of the signal generator waveform might violate setup time, which could cause the oscilloscope acquisition to start one sample late. Alternatively, if the falling edge of the marker might violate hold time, this could cause the measurement to stop one sample early. Furthermore, if the marker timing is marginal, the measurement duration could vary randomly across measurements. This non-synchronized measurement setup can be problematic for accurate high speed pulse measurements and could potentially result in increased or higher error margins with regard to the measurements. Accordingly, in order to better synchronize the devices to obtain more accurate sample level accurate waveform measurements and with reduced error, improvements in the field are desirable.

### SUMMARY

Embodiments described herein relate to systems, memory media, and methods for sample accurate waveform measurement synchronization. In some embodiments, the communications devices described herein can operate in the radio frequency (RF) and can be called RF devices.

In some embodiments, a method for synchronizing radio frequency (RF) devices can include receiving, a first stimuli signal including a maker signal from a first RF device and an output signal from a second RF device, wherein the output signal can be based at least in part on a second stimuli signal including a pulse waveform transmitted from the first RF device to the second RF device. The method can include digitizing the pulse waveform, measuring delay values between a first sample of the first stimuli signal and the digitized pulse waveform, and adjusting a timing of the marker signal. The method can include performing one or more pulse delay measurements associated with the first stimuli signal and the output signal as well as calculating a trigger delay. The method can also include performing, using the trigger delay, one or more measurements associated with a device under test (DUT).

According to some embodiments, measuring the one or more delay values can include sweeping a marker delay in increments while measuring delays between the first sample of the first stimuli signal and the digitized pulse waveform. Additionally or alternatively, when the delays decrease by a trigger clock period, said adjusting can include adjusting the timing by half of the trigger clock period. In some embodiments, said calculating can include calculating an average of the one or more pulse delay measurements and rounding the average to the nearest trigger clock period.

According to further embodiments, said performing can be according to one or more measurement modes of the second RF device including a voltage measurement mode or a current measurement mode. In some embodiments, the second RF device can be communicatively coupled to the DUT and the output signal can be based at least in part on the DUT's response to the first stimuli signal. Additionally or alternatively, the second stimuli signal can be associated with an analog signal path delay and the first stimuli signal can be associated with a digital trigger path delay.

In some embodiments, a system for synchronizing radio frequency (RF) devices can include a signal generator, a remote unit (RU) communicatively coupled to a device under test (DUT), and an oscilloscope. Furthermore, the system can be configured to
input, from the signal generator, a first input stimuli signal into the RU wherein the first stimuli signal comprises a pulsed waveform and input, from the signal generator, a second input stimuli signal into the oscilloscope. Furthermore, the system can be configured to receive, at the oscilloscope, the second input stimuli signal from the signal generator and an output signal from the RU. In some embodiments, the output signal can be based at least in part on the first input stimuli signal. Additionally, the system can be configured to, at the oscilloscope, digitize the pulse waveform and measure one or more delay values between a first sample of the second input stimuli signal and the digitized pulse waveform. Furthermore, the system can be configured to adjust, based at least in part on the one or more delay values, a timing of the marker signal and perform one or more pulse delay measurements associated with the second input stimuli signal from the signal generator and the output signal from the RU. According to further embodiments, the system can be configured to calculate, based on the one or more pulse delay measurements, a trigger delay for the signal generator and apply, at the signal generator, the trigger delay.

In some embodiments, a non-transitory computer-readable storage medium can store program instructions which, when executed by a computer, are configured to operate a calibration system to synchronize radio frequency (RF) devices. Additionally or alternatively, the calibration system can include the computer as well as first, second, and third RF devices, and said operating can include transmitting, from the first RF device, a first stimuli signal to the second RF device. According to some embodiments, the first stimuli signal can include a pulsed waveform and said operating can further include transmitting, from the first RF device, a second stimuli signal comprising a marker signal to a third RF device. Additionally, said operating can include receiving, at the third RF device, the second stimuli signal from the first RF device and an output signal from the second RF device. Additionally or alternatively, the output signal can be based at least in part on the first stimuli signal. Furthermore, said operating can include, at the third RF device, digitizing the pulse waveform and measuring one or more delay values between a first sample of the second stimuli signal and the digitized pulse waveform. In some embodiments, said operating can include adjusting, based at least in part on the one or more delay values, a timing of the marker signal and performing one or more pulse delay measurements associated with the second stimuli signal from the first RF device and the output signal from the second RF device. According to further embodiments, said operating can include calculating, based on the one or more pulse delay measurements, a trigger delay and applying, at the first RF device, the trigger delay.

Note that the techniques described herein can be implemented in and/or used with a number of different types of devices, including but not limited to RF devices such as waveform or signal generators, oscilloscopes, remote sensing units, devices under test, base stations, access points, cellular phones, portable media players, tablet computers, wearable devices, RF semiconductor components, RF power amplifiers, Front End Modules, transceivers, and various other computing devices.

This Summary is intended to provide a brief overview of some of the subject matter described in this document. Accordingly, it will be appreciated that the above-described features are only examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

A better understanding of the present invention can be obtained when the following detailed description of the preferred embodiments is considered in conjunction with the following drawings.

FIG. 1 illustrates an example system 100 that is configured to perform synchronization of RF devices to provide sample accurate waveform measurements, according to some embodiments;

FIG. 2 illustrates an example communication bus for connecting a computer to a synchronization system, according to some embodiments;

FIG. 3 illustrates example aspects of Ultra-Fast Parametric I-V (UFPIV) measurement acquisition triggering, according to some embodiments;

FIGS. 4A-B illustrate example aspects of UFPIV measurement acquisition triggering solutions, according to some embodiments;

FIG. 5 illustrates aspects and portions of an example oscilloscope schematic, according to some embodiments;

FIG. 6 illustrates example aspects of a system schematic for trigger timing and delay(s) for a DUT, according to some embodiments;

FIG. 7 illustrates an example analog output to marker timing without calibration, according to some embodiments;

FIGS. 8A-B illustrate example aspects of a trigger calibration procedure, according to some embodiments;

FIG. 9 illustrates example aspects of trigger timing and delay calibration procedures, according to some embodiments; and

FIG. 10 is a flow diagram illustrating an example method of synchronization of RF devices for sample accurate waveform measurements, according to some embodiments.

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

### Acronyms

Various acronyms are used throughout the present disclosure. Definitions of the most prominently used acronyms that can appear throughout the present disclosure are provided below:
RF: Radio Frequency
DUT: Device Under Test
RSU: Remote Sensing Unit
RU: Remote Unit
PFI: Programmable Function Interface
DAC: Digital-to-Analog Converter
ADC: Analog-to-Digital Converter
FPGA: Field Programmable Gate Array
FIFO: First In, First Out
DMA: Direct Memory Access
PIV: Pulsed Current-Voltage
UFPIV: Ultra-fast Parametric I-V Measurements
BRAM: Block Random Access Memory
FIR: Finite Impulse Response
AI: Analog Input

### Terminology

The following is a glossary of terms used in the present document.
Memory Medium—A memory medium is a medium configured for the storage and retrieval of information. Examples of memory media include: various kinds of semiconductor memory such as RAM and ROM; various kinds of magnetic media such as magnetic disk, tape, strip and film; various kinds of optical media such as CD-ROM and DVD-ROM; various media based on the storage of electrical charge and/or other physical quantities; media fabricated using various lithographic techniques; etc. The term “memory medium” can also include a set of two or more memory media which reside at different locations, e.g., at different computers that are connected over a network.
Programmable Hardware Element—a hardware device that includes multiple programmable function blocks connected via a programmable interconnect. Examples include FPGAs (Field Programmable Gate Arrays), PLDs (Programmable Logic Devices), FPOAs (Field Programmable Object Arrays), and CPLDs (Complex PLDs). The programmable function blocks can range from fine grained (combinatorial logic or look up tables) to coarse grained (arithmetic logic units or processor cores). A programmable hardware element can also be referred to as “reconfigurable logic”.
Program—the term “program” is intended to have the full breadth of its ordinary meaning. As used herein, the term “program” includes within its scope of meaning: 1) a software program which is stored in a memory and is executable by a processor, or, 2) a hardware configuration program useable for configuring a programmable hardware clement. Any of the method embodiments described herein, or, any combination of the method embodiments described herein, or, any subset of any of the method embodiments described herein, or, any combination of such subsets can be implemented in terms of one or more programs.
Software Program—the term “software program” is intended to have the full breadth of its ordinary meaning, and includes any type of program instructions, code, script and/or data, or combinations thereof, that can be stored in a memory medium and executed by a processor or computer system. Example software programs include: programs written in text-based programming languages such as C, C++, Java™, Pascal, Fortran, Perl, etc.; graphical programs (programs written in graphical programming languages); assembly language programs; programs that have been compiled to machine language; scripts; and other types of executable software. A software program can comprise two or more subprograms that interoperate in a specified manner.
Hardware Configuration Program—a program, e.g., a netlist or bit file, that can be used to program or configure a programmable hardware element.
Computer System-any of various types of computing or processing systems, including a personal computer (PC), a mainframe computer system, a workstation, a laptop, a network appliance, an Internet appliance, a hand-held or mobile device, a personal digital assistant (PDA), a television system, a grid computing system, or other device or combinations of devices. In general, the term “computer system” can be broadly defined to encompass any device (or combination of devices) having at least one processor that is configured to execute instructions that are stored on a memory medium.
Measurement Device-includes instruments, data acquisition devices, smart sensors and any of various types of devices that are operable to acquire and/or store data. A measurement device can also optionally be further operable to analyze or process the acquired or stored data. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card, a video capture board, a smart camera, a motion control device, a robot having machine vision, and other similar types of devices. Example “stand-alone” instruments include oscilloscopes, multimeters, signal analyzers, signal demodulators, arbitrary waveform generators, spectroscopes, and similar measurement, test, or automation instruments.

A measurement device can be further operable to perform control functions, e.g., in response to analysis of the acquired or stored data. For example, the measurement device can send a control signal to an external system, such as a motion control system or to a sensor, in response to particular data. A measurement device can also be operable to perform automation functions, e.g., can receive and analyze data, and issue automation control signals in response.

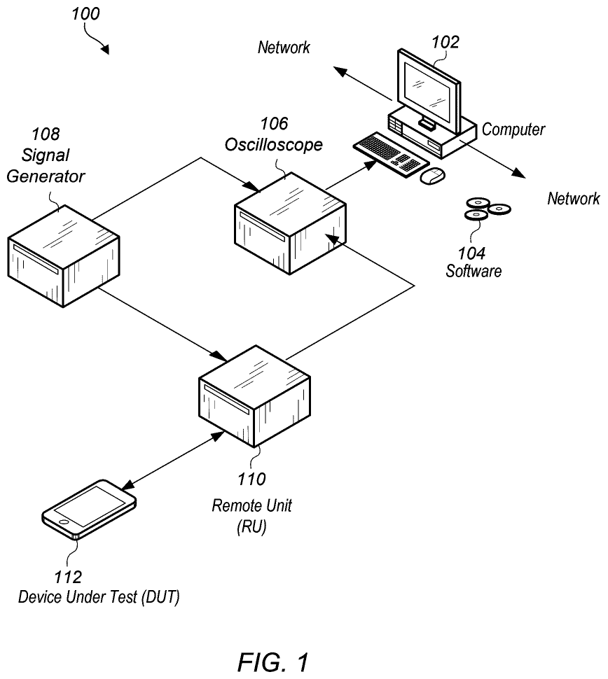

### FIG. 1—Example System for Synchronizing RF Devices

FIG. 1 illustrates an example system 100 that is configured to perform synchronization of RF devices to provide sample accurate waveform measurements, according to some embodiments. For example, a computer 102 can be used by a user to conduct the synchronization process and can be connected to a network and to the measurement apparatus. Software 104 can be installed on the computer to conduct the delay measurement process. The computer 102 can be connected to any of a variety of signal generating apparatuses, according to various embodiments. For example, the computer can be connected to an oscilloscope (O-scope) 106. Additionally and according to some embodiments, the oscilloscope 106 can be connected to a signal generator (e.g., waveform or function generator) 108 and/or a remote unit (RU) 110 such as a remote sensing unit (RSU) (e.g., also known as a remote head module or remote head unit). In some embodiments, the oscilloscope 106 can also be connected to an output of the RU 110. According to some embodiments, the RU 110 can supply a signal from the signal generator 108 to a device under test (DUT) 112 and output a response signal from the DUT 112 to the oscilloscope 106. Additionally or alternatively, the oscilloscope 106, signal generator 108, and/or RU 110 can be comprised within the computer 102, which can be directly connected to the DUT 112, according to some embodiments.

Embodiments presented herein are directed toward performing synchronization of RF devices for measuring the electrical characteristics (e.g. radio frequency (RF) performance, power added efficiency) of a DUT (e.g., DUT 112). Additionally, while some RF devices can operate within the RF frequency range (e.g., approximately 30 Hertz (Hz) to 300 gigahertz (GHz)), said RF devices can also operate in other frequency ranges (e.g., less than 30 Hz and greater than 300 GHz), according to some embodiments. Furthermore, while some RF devices can operate transmit signaling without the use of physical cabling (e.g., wireless transmission), some RF devices can utilize physical cabling (which can have known propagation and impedance characteristics) to transmit signaling, according to some embodiments. Accordingly and in some instances, these known propagation and impedance characteristics can be beneficial for aiding the user in calculating triggering and timing parameters for use in synchronizing high-speed pulse measurement instruments. For example, in some embodiments, the DUT 112 can be stimulated with a control signal (e.g. from an arbitrary waveform generator (AWG) such as signal generator 108, a vector signal generator (VSG) or an RF signal generator (RFSG), which can be comprised within a PXI, VXI, a computer, or some other signal generator, in various embodiments). The timing of the AWG and VSG output signals can be aligned such that the DUT exhibits optimal electrical characteristics. In some embodiments, the signal characteristics can be measured with an oscilloscope such as oscilloscope 106, a vector signal analyzer (VSA), which can be comprised within any of a peripheral component interconnect (PCI) eXtensions for Instrumentation (PXI), or other computer systems.

In some embodiments, separate devices can be used to perform some of the functions (e.g. the AWG, VSG, VSA, etc.) described above. These dedicated devices, which can be known in the art as “box” type instruments, can also be connected to a computer system. In some embodiments, the connected computer system can be configured to receive outputs from or provide inputs to the dedicated instruments. The connected computer system can also, in some embodiments, collect and store data or display outputs from the devices.

The illustrated embodiment shows an example system that can be used to perform calibration of a DUT. Calibration can be performed as a production test step during device manufacture or assembly. In some embodiments, system 100 can be also be used for device characterization or production test. In some embodiments, calibration can be performed to establish a suitable temporary condition for measurements. In other embodiments, measurements can be used for integration with the final product.

In some embodiments, the measured timing characteristics and delays (which can be used for accurate synchronization of RF devices) varies based on the configuration of the DUT 112 as well as the other instruments in the system (e.g., signal generators, oscilloscopes, RUs, etc.). Some non-limiting examples of configurational changes that can cause the delay to vary are different power levels, different frequencies and patterns supplied as a signal, different filters applied to/within the DUT, as well as different frequency ranges, etc. In some embodiments, a computer readable memory medium can store the measured timing characteristics and delays for each configuration along with a description of the respective configuration of the DUT. Additionally, different signal paths associated with different configurations can be an important consideration for measuring the timing and triggering characteristics in addition to delay.

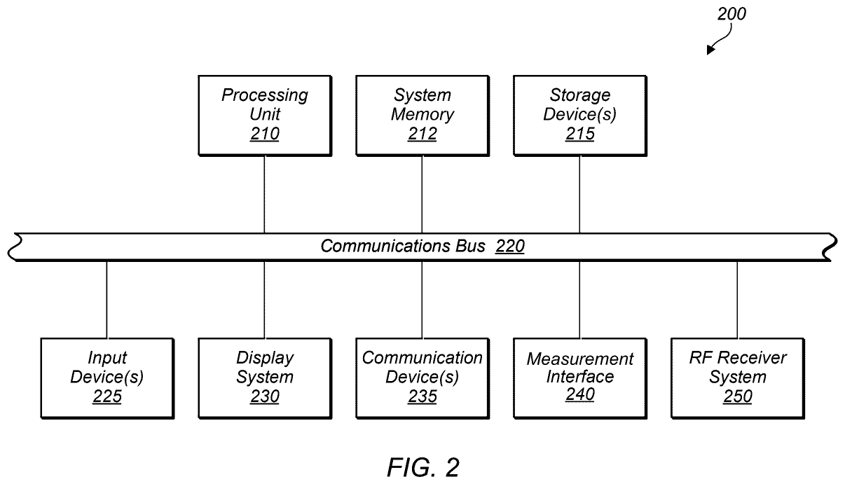

### FIG. 2—Example Communications Bus Device

FIG. 2 illustrates an example communication bus device 200 including a communications bus 220 for connecting a computer such as 102 to the synchronization system 100, according to some embodiments. The communications bus 220 can be coupled to a processing unit 210, a system memory 212, and storage device(s) 215. The communications bus 220 can be further coupled to an input device(s) 225 to receive input, a display system 230, a communications device(s) 235, a measurement interface 240, and an RF receiver system 250. The RF receiver system 250 can be configured to receive inputs from the oscilloscope 106, signal generator 108, RU 110, DUT 112, computer 102, or other components of the system. In some embodiments, the RF receiver system receives signals from each component of the synchronization system 100. The display system 230 that can facilitate user interface with the synchronization system 100. The measurement interface 240 can facilitate communication between the communications bus and the computer 102, synchronization system 100, and/or a timing, triggering, and delay measuring apparatus. The RF receiver system 250 can be configured to receive radio frequency signals from said timing, triggering, and delay measuring apparatus and/or synchronization system 100. In some embodiments, the RF receiver system 250 can be comprised within an external AWG or other signal generator.

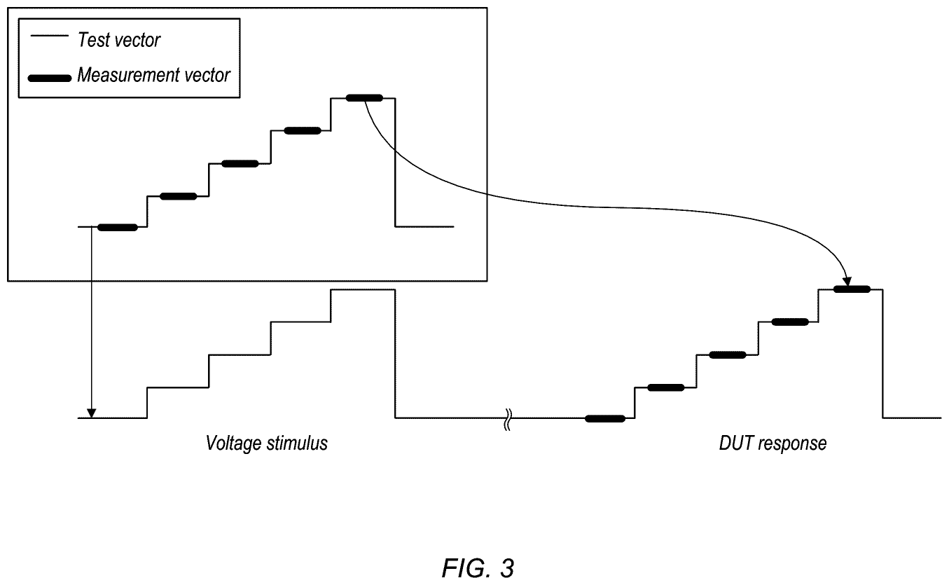

### FIG. 3—Ultra-Fast Parametric I-V (UFPIV) Measurement Acquisition Triggering

FIG. 3 illustrates example aspects of UFPIV acquisition triggering, according to some embodiments. For example, when users of high-speed pulse measurement systems specify their test vectors, they typically define both the voltage stimulus signal as well as a set of measurement specifications. Accordingly, the timing of the measurement specifications can be considered to be relative to the timing of the voltage stimulus signal. For example, FIG. 3 illustrates a voltage stimulus signal (associated with a test vector) which is supplied to a DUT and a measured DUT response. Furthermore, the DUT is measured according to the measurement vectors associated with the DUT response to the voltage stimulus signal, according to some embodiments.

However, in some instances, it can be beneficial to capture the DUT response associated with the voltage stimulus signal. For example, as the DUT response occurs sometime after the voltage stimulus reaches an RU, the user can define arbitrary start and aperture times for each measurement, according to some embodiments. Accordingly, it can be beneficial to provide a triggering solution for UFPIV measurements that enables the user to capture the DUT response with sample level (or sub-sample level (e.g., +/−0.5 samples)) accuracy.

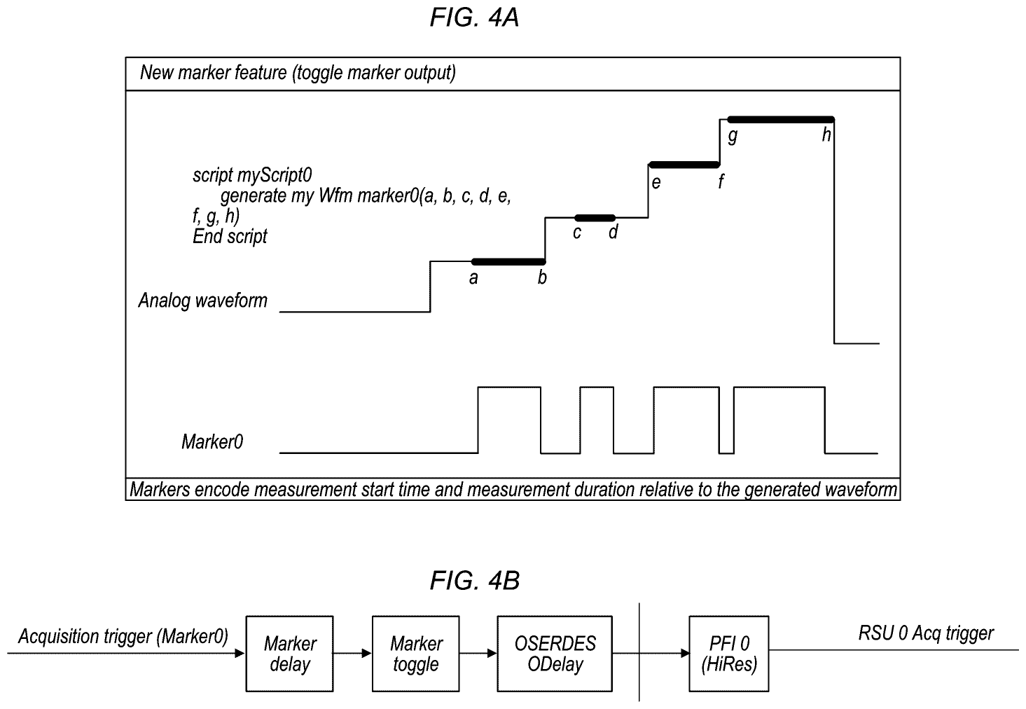

### FIGS. 4A-B—UFPIV Measurement Acquisition Triggering Solutions

FIGS. 4A-B illustrate example aspects of UFPIV measurement acquisition triggering solutions, according to some embodiments. For example, FIG. 4A illustrates an analog waveform (supplied by a signal generator such as an AWG) which can drive the voltage stimulus to a DUT through a RU. Accordingly, an oscilloscope can capture the DUT's response through the RU, according to some embodiments.

In some embodiments, the AWG can source the acquisition trigger with a marker exported through a Programmable Function Interface (PFI) line and the marker can be characterized as a digital signal that is aligned to a particular digital to analog converter (DAC) sample of the analog output. Markers can be useful in pulse measurement applications because the acquisition trigger should be synchronous to the voltage stimulus. However, some AWGs' pulse marker behavior is not sufficient to serve as the acquisition trigger. For example and in some instances of pulse behavior, the marker pulse width can be fixed at 200 nanoseconds (ns) while the minimum time between markers can be 400 ns.

To overcome this potential limitation, it can be beneficial to add new toggle marker conditioning logic to the AWG's FPGA. For example, when the marker toggle mode is enabled, the marker output can toggle a state with each marker produced by the waveform engine. Accordingly, this marker toggle mode can enable the generation of an arbitrary digital waveform that is aligned to the analog output, according to some embodiments. For example, FIG. 4A illustrates the Marker0 waveform that is aligned to the analog waveform as well as the different measurement vectors associated with the test vector and voltage stimulus signal. In other words, the marker signal encodes and displays a measurement start time and a measurement duration relative to the generated waveform, according to some embodiments.

In some embodiments, an example code block (e.g., software script) which can be used to generate a marker signal (e.g., such as that shown in FIG. 4A) can be characterized as:

Script myScript( )
generate myWfm marker0(a, b, c, d, e, f, g, h)
end script

According to some embodiments, script-based markers (e.g., as characterized in the code block above) can also be replaced with data-based markers. For example, for data-based markers, the toggle marker behavior can be the same except for data-based markers such that the markers are embedded in the DAC samples instead of in script-memory, according to some embodiments.

FIG. 4B illustrates an example portion of schematics associated with UFPIV measurement acquisition triggering solutions, according to some embodiments. For example and according to some embodiments, it can be beneficial to add a high-resolution marker delay first in, first out (FIFO) that allows marker signals (e.g., Marker0) to be delayed relative to the analog output in 78.125 picosecond (ps) increments up to approximately 10.24 microseconds (us) (as some examples). This adjustable delay can help precisely align the marker-based acquisition trigger to the DUT response, according to some embodiments. Accordingly and as shown in FIG. 4B, the Acquisition Trigger (e.g., Marker0) can pass through a Marker Delay, Marker Toggle, OSERDES O Delay, and PFI 0 (HiRes) components to condition the marker signal, according to some embodiments.

Furthermore, when the marker signal is received at the oscilloscope, the oscilloscope can begin to acquire data when the marker is high and stop acquiring data when the marker is low (e.g., level trigger). According to further embodiments, new triggering logic could be added to oscilloscopes' FPGAs to allow them to sample the PFI trigger inputs at 200 megahertz (MHz) in order to match the analog to digital converter (ADC) sample rate (e.g., 200 mega samples per second (MS/s)). In doing so, this can enable the AWG to start and stop acquisition with ADC sample-level accuracy which can further result in pulse or waveform measurements with lower error rates (e.g., lower error bars) which can be used to graphically or visually represent variability of the data and to indicate the error or uncertainty in a reported measurement, according to some embodiments.

Furthermore and according to some embodiments, independent acquisition and trigger engines can be created for each of the oscilloscope channels which can allow for each channel to trigger and acquire data independently.

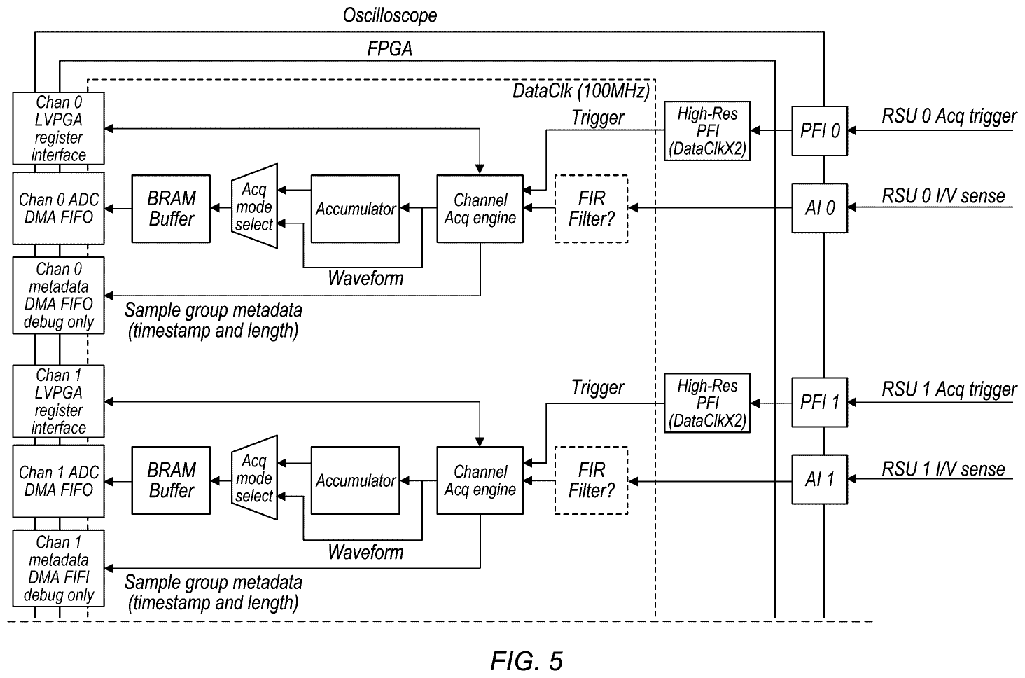

### FIG. 5—Example Oscilloscope Schematic

FIG. 5 illustrates aspects and portions of an example oscilloscope schematic, according to some embodiments. For example, the oscilloscope can have multiple input channels such as PFI 0 to receive a RSU 0 Acq (e.g., Acquisition) trigger, analog input (AI) 0 to receive a RSU 0 current/voltage (I/V) sense as well as PFI 1 to receive a RSU 1 trigger and AI 1 to receive a RSU 1 I/V sense, according to some embodiments. Furthermore, the AI 0 (associated with channel 0) can forward a sensed signal through multiple components of the FPGA of the oscilloscope (and associated with a data clock (DataClk) operating at 100 MHz (as one example). For example, the AI 0 can forward a sensed signal to the FPGA which can include the signal interacting with multiple components of the oscilloscope including (but not limited to) a finite impulse response (FIR) Filter, a Channel Acq Engine, an Accumulator, an Acq Mode Select, a block random access memory (BRAM) Buffer, and a Chan 0 ADC DMA FIFO, a Chan 0 metadata DMA FIFO and a FPGA register interface, according to some embodiments. Furthermore, the PFI 0 (also associated with channel 0) can forward a sensed signal to the FPGA which can include the signal interacting with multiple components of the oscilloscope including (but not limited to) the aforementioned components as well as a High-Res PFI (DataClkX2) which can correspond to a higher clock rate (e.g., 200 MHz). Similarly, PFI 1 and AI 1 can forward signals to similar components associated with channel 1.

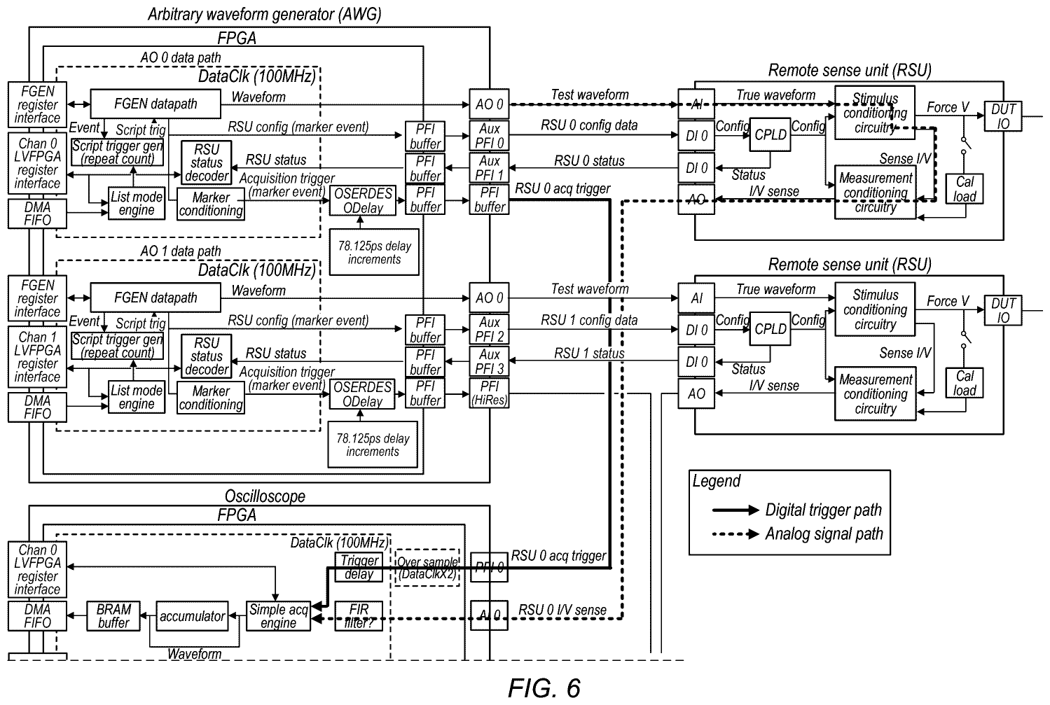

### FIG. 6—System Schematic for Trigger Timing and Delay(s) for a DUT

FIG. 6 illustrates example aspects of a system schematic for trigger timing and delay(s) for a DUT, according to some embodiments. For example, FIG. 6 illustrates two possible RUs (e.g., RSUs) connected to one or more DUTs via an input/output (I/O) port. The RUs can include various inputs, outputs, loads, circuitry, and components including AI, analog output (AO), digital inputs (DIs), calibration (Cal) load(s), stimulus conditioning circuitry, measurement conditioning circuitry, and complex programmable logic devices (CPLDs), according to some embodiments.

Furthermore, FIG. 6 illustrates a portion of the oscilloscope described above and illustrated in FIG. 5 as well as the digital trigger path from the AWG to the oscilloscope and the analog signal path from the AWG to the to the oscilloscope via the RU (and DUT). In other words, the example systems illustrated by FIGS. 5 and 6 may operate together as part of a larger system. Additionally, FIG. 6 illustrates various inputs, outputs, loads, circuitry, and components of the AWG and its FPGA including AOs, Auxiliary (Aux) PFIs, and Hi-Resolution (Res) PFIs, PFI buffers, OSERDES ODelay (which can incorporate one or more 78.125 ps delays to a marker signal), register interfaces, DMA FIFOs, script trigger generators, list mode engines, RU status decoders, and marker conditioning circuitry, according to some embodiments.

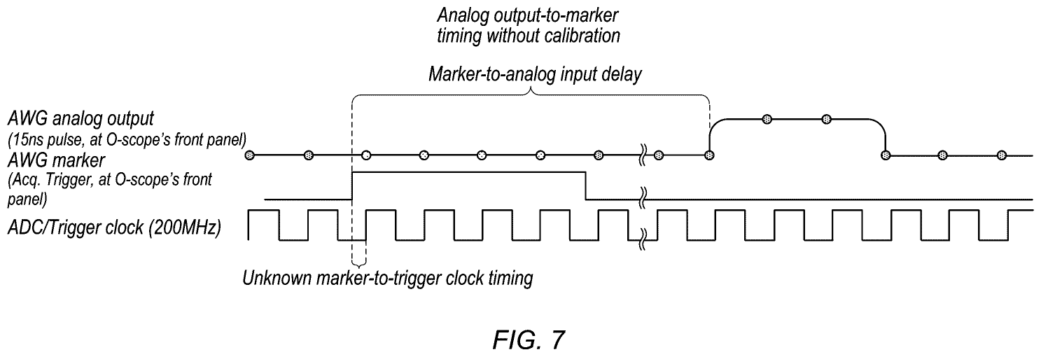

### FIG. 7—Analog Output to Marker Timing Without Calibration

With the improvements to the AWG, oscilloscope, and marker signaling described above and with respect to FIGS. 4-6, the AWG can precisely control the start and stop time of each measurement with respect to the voltage stimulus. However, in order to synchronize the devices to obtain sample level accurate waveform measurements, additional steps can be necessary. More specifically, in order to better synchronize the measurement equipment (e.g., signal generator, RU, and oscilloscope, etc.), it can be beneficial to tune the alignment of the marker-based acquisition trigger with respect to the oscilloscope's trigger clock to ensure that oscilloscope can deterministically capture the samples of interest, according to some embodiments. For example, the AWG and oscilloscope sample clocks can be phase-locked since they will be configured to use the same reference clock source (e.g., PXIe_Clk100 as one example), according to some embodiments.

However, in some instances the timing relationship between the AWG's marker and the oscilloscope's 200 MHz trigger clock can be unknown to the user. Accordingly, the rising edge of the marker might violate setup time, which could cause the acquisition to start one sample late. Additionally or alternatively, the falling edge of the marker might violate hold time, which could cause the measurement to stop one sample early. Furthermore, if the marker timing is marginal, the measurement duration could vary randomly across measurements, according to some embodiments.

This non-synchronized measurement setup can be problematic for waveform acquisition modes since they can potentially rely on the AWG's marker configuration to determine how to parse (e.g, extract relevant information from potentially unstructured data sources and transform it into a more structured format that can be more easily analyzed) the ADC samples coming from the DMA FIFO into independent measurements, according to some embodiments.

For example, FIG. 7 illustrates an example analog output to marker timing without calibration and further shows the consequences of trigger delay and trigger timing issues, according to some embodiments. As illustrated in FIG. 7, the AWG can generate a 15 ns pulse waveform and 20 ns-wide marker (aligned at the AWG's front panel), according to some embodiments. FIG. 7 also illustrates the potential timing between these signals at the O-scope's front panel and that it is possibly not clear when the measurement may start or stop since the marker-to-trigger clock timing is unknown. Additionally, FIG. 7 illustrates that it is possibly not clear which samples will be captured relative to the pulsed waveform since the marker-to-analog input delay is unknown. Accordingly, it can be beneficial to introduce a system-level trigger calibration procedure to correct these problems. For example, to ensure measurement integrity, aligning the marker relative to the 200 MHz trigger clock to guarantee that the marker will always meet timing could result in improved sample level accurate measurements. In other words, it can be beneficial to determine the marker delay required to align the acquisition trigger with the DUT's response, according to some embodiments.

Furthermore, it can be beneficial to align the marker with the DUT's response at the input of the acquisition engine for each channel, according to some embodiments. To achieve this, a user can measure the relative delay of the analog signal and digital trigger paths between the AWG and O-scope (e.g., as shown in FIG. 6). For example, the digital trigger path delay can be associated with cable delays between the AWG and the O-scope PFIs as well as delays between the O-scope's front panel PFI connector and acquisition engine (e.g., FPGA), according to some embodiments. Furthermore, the analog signal path delay (e.g., as shown in FIG. 6) can include cable delay between the AWG and the RSU, delay through the RSU (which can vary according to RSU configuration(s)), cable delay between the RSU and O-scope front panel (e.g., connected with an SubMiniature version A (SMA) connector), delay through the O-scope's analog front end, delay through the ADC, as well as delay through a digital filter to the acquisition engine (e.g., FPGA), according to some embodiments. In some instances, the analog signal path delay can be much larger than the digital trigger path delay (on the order of microseconds). However, once the difference in delay between these paths has been measured or determined, the AWG's marker output can be delayed to align it to the DUT's response at the input of the acquisition engine, according to some embodiments.

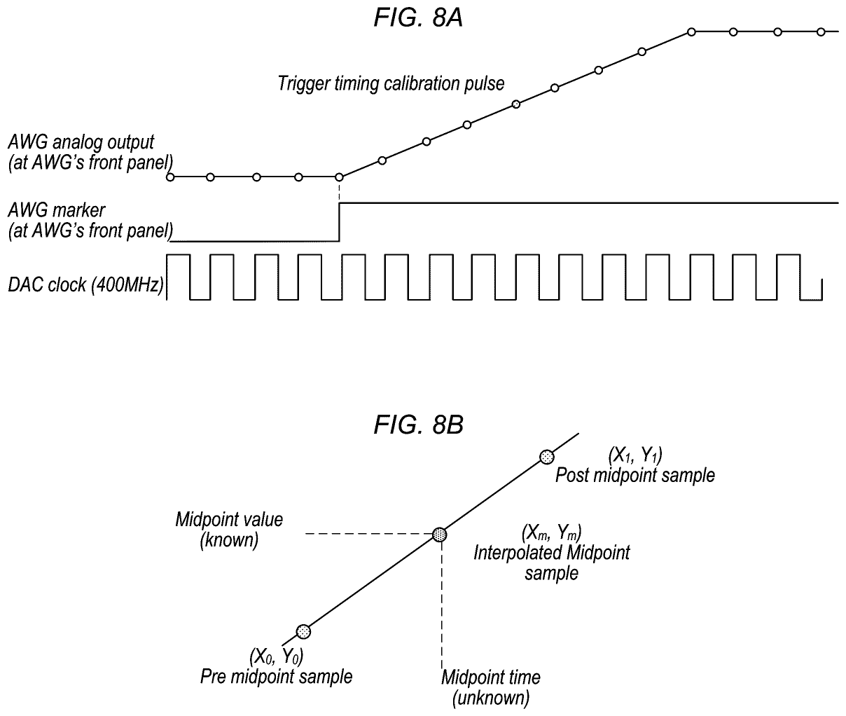

### FIGS. 8A-B—Trigger Timing Calibration Procedure

FIGS. 8A-B illustrate example aspects of a trigger calibration procedure, according to some embodiments. For example, FIG. 8A illustrates a trigger timing calibration pulse at the AWG's front panel via an analog output, according to some embodiments. FIG. 8A additionally illustrates the AWG marker signal at its front panel as well as a DAC clock operating at a 400 MHz clock rate, according to some embodiments.

Accordingly and as part of a trigger timing calibration procedure using the illustrated trigger timing calibration pulse of FIG. 8A, a user can make a pulse delay measurement which is the difference in delay between the marker-based digital trigger path and the analog signal path, according to some embodiments. For example, to make the pulse delay measurement(s), the AWG can be used to generate a pulsed waveform and marker signal (aligned to the pulsed waveform). The O-scope can then begin to acquire data upon receiving the marker and digitize the delayed pulse waveform, according to some embodiments. Furthermore, the pulse delay can be measured by calculating the time between the first sample and the digitized pulse, according to some embodiments.

For example, a pulse delay measurement methodology can include steps such as configuring the oscilloscope by setting the reference clock source (e.g., to PXIe_Clk100 as one example), setting the sample clock rate (e.g., to 200 MHz as one example), enabling the UFPIV waveform acquisition mode, configuring and starting the UFPIV ADC DMA FIFOs, configuring the UFPIV trigger source, and setting the vertical parameters to the desired values. Additionally, the pulse delay measurement methodology can include steps such as configuring the AWG by setting the reference clock source (e.g., to PXIe_Clk100 as one example), setting the sample clock rate (e.g., to 400 MHz as one example), setting the vertical parameters to the desired values, enabling UFPIV marker toggle mode, and configuring the AWG to generate a single pulse waveform with example characteristics such as a 100 ns rise time, a 500 ns pulse width. In some instances, a 100 ns (or potentially faster) rise time can be necessary as a slower rise time can possibly prevent the AWG, RU, and O-scope from filtering the rising edge of the pulse, according to some embodiments. Additionally, the pulse delay measurement methodology can include steps such as configuring the AWG such that the gain and offset of the pulse match the dynamic range of the oscilloscope, according to some embodiments.

Additionally, the pulse delay measurement methodology can include steps such as configuring the AWG to generate and configure a marker to align to the first sample of the analog pulse waveform, according to some embodiments. Furthermore and in some instances, in order to avoid just performing a digital alignment, it can be necessary for the AWG signal rise time to be fast enough such that it rises greater than the system noise but slow enough that it captures multiple measurement samples. Additionally, the width of the marker should typically be larger than a maximum expected digital trigger-to-analog signal delay (e.g., approximately 5 μs as one example), according to some embodiments. Furthermore, the sample index of the marker-based trigger can be a multiple of two (e.g., 2) to ensure that the marker will be aligned to a trigger clock boundary (e.g., 200 MHz as one example), according to some embodiments. Furthermore and as one example (and further depending on the settings of the instrumentation in the system related to the trigger signal, clock frequency, etc.), with a rise time of 100 ns, the marker can assert on (e.g, be located at) the 20th sample of the rising edge, according to some embodiments. The pulse delay measurement methodology can further include generating the waveform and fetching the acquired samples from the UFPIV ADC DMA FIFO, according to some embodiments.

FIG. 8B illustrates example aspects for calculate the trigger-to-pulse delay, according to some embodiments. For example, the pulse delay measurement methodology can further include using a linear interpolation to determine the time of the mid-point marker sample. In some embodiments, the mid-point marker sample can fall between ADC samples. Accordingly, given the ADC samples before and after the midpoint, linear interpolation can be used to find the time of the marker sample. For example and as illustrated in FIG. 8B, a Pre midpoint sample can correspond to sample values X₀, Y₀ (e.g., Pre midpoint sample=(X₀, Y₀)), a post midpoint sample can correspond to sample values X₁, Y₁ (e.g., Post midpoint sample=(X₁, Y₁)), and an Interpolated midpoint sample can correspond to sample values Xₘ, Yₘ (e.g., Interpolated midpoint sample=(Xₘ, Yₘ)), according to some embodiments. Accordingly and in some instances, the pulse midpoint time and subsequent pulse delay can be calculated according to the following formulas:

$$Pulse midpoint time = {X}_{m} = {X}_{1} - \frac{( {X}_{1} - {X}_{0} ) ( {Y}_{1} - {Y}_{m} )}{{Y}_{1} - {Y}_{0}}$$

$$Pulse delay = Pulse midpoint time - \frac{pulse rise time}{2}$$

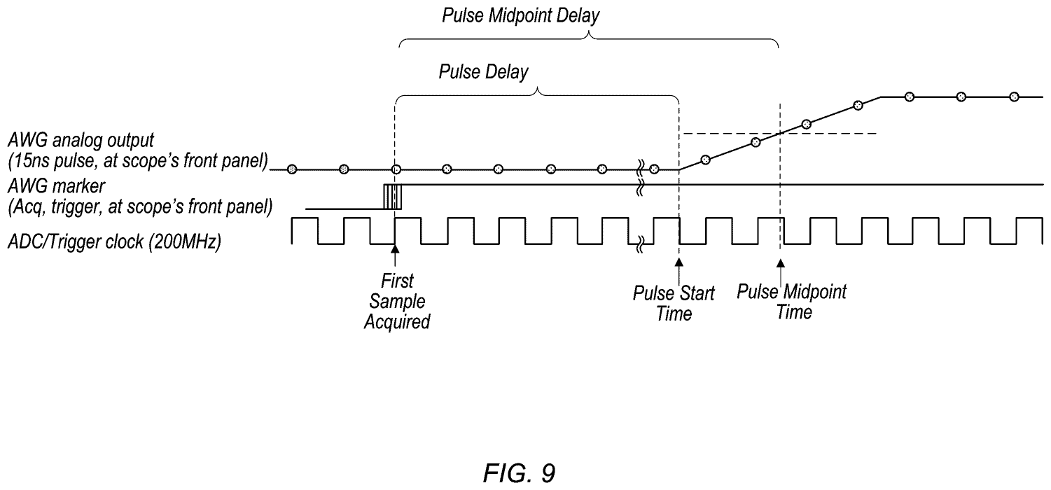

### FIG. 9—Trigger Timing and Delay Calibration

FIG. 9 illustrates example aspects of trigger timing and delay calibration procedures, according to some embodiments. Additionally FIG. 9 illustrates the time of the interpolated marker sample which indicates the delay between the marker-based trigger and the pulsed waveform, according to some embodiments.

In some embodiments related to FIG. 9, trigger calibration consists of a trigger timing calibration procedure in which the marker-based trigger timing is measured and tuned (e.g., adjusted) and a trigger delay calibration procedure in which the analog signal-to-trigger path delay is measured and compensated for, according to some embodiments.

According to some embodiments, particular settings can be used for the trigger timing calibration procedure. For example, the remote head (e.g., RU or RSU) can be set to a fast I/V mode, set to measure voltage, the DUT can be disconnected from the remote head, and/or the current can be set to a 10 milliampere (mA) range, according to some embodiments. Additionally or alternatively, the AWG gain can be set to 2.5 volts (V), according to some embodiments. While these current and voltage settings may be used for the trigger timing calibration procedure, other values of current and voltage (among other possible parameters) may be used in different scenarios and/or setups, according to some embodiments.

In some instances, the trigger alignment calibration procedure can be performed to tune the alignment of the marker-based acquisition trigger with respect to the oscilloscope's trigger clock to ensure that the oscilloscope can deterministically capture the samples of interest. For example, a preferred trigger alignment can be found by sweeping the marker delay in small increments (e.g., in 78.125 ps increments as one example) while measuring the trigger-to-pulse delay. Accordingly, a user can determine that the marker-based trigger is near a rising edge of the trigger clock when the trigger-to-pulse delay value decreases by a single (e.g., 1) trigger clock period. In response, the user can then adjust the marker delay by +/−0.5 (e.g., half) a trigger clock period to place the marker in the middle of the trigger clock, according to some embodiments. For example, an example algorithm to align a marker to a trigger clock edge can be characterized by the following code block or script:

```
Set marker delay to 0
Set maxPulseDelay to −Inf
Set minPulseDelay to +Inf
Set triggerClockEdgeFound to false
while (not triggerClockEdgeFound) do
  for (i < 50) do
    pulseDelays[i] = measurePulseDelay
  end
  maxPulseDelay = max (maxPulseDelay, pulseDelays)
  minPulseDelay = min (minPulseDelay, pulseDelays)
  If (maxPulseDelay − minPulseDelay >= 0.5 trigger clock periods)
    triggerClockEdgeFound = true
  else
  makerDelay = markerDelay + 78.125ps
end
```

According to some embodiments, the algorithm can produce an error response and stop the trigger timing calibration procedure if minPulseDelay exceeds 100 ns, if the maxPulseDelay exceeds 1 μs, and/or a jitter of the maxPulseDelay exceeds 10 ns (among various other possible thresholds).

Accordingly, once the marker delay to align the trigger to the rising edge of the trigger clock has been found, the user can calculate the minimum marker adjustment necessary to align the marker-based trigger to the nearest falling edge of the trigger clock, according to some embodiments. For example, the user can utilize the following equations to calculate the trigger timing constant and the trigger timing constant range:

$$Trigger Timing Constant = ( markerDelay + 0.5 triggerClockPeriod ) mod triggerClockPeriod$$

$$Trigger Timing Constant Range = [ 0 , triggerClockPeriod ]$$

Accordingly, once the trigger timing constant and the trigger timing constant range have been calculated, the user can configure the marker delay according to the calculated values, according to some embodiments. In some embodiments, the marker delay can only be adjusted in trigger clock sample period increments after the marker alignment value has been configured in order to ensure that the trigger continues to meet timing after adjusting the marker delay.

Once the marker delay has been adjusted, the user can proceed to the trigger delay calibration procedure in order to find the marker delay required to align the acquisition trigger with the DUT's measured response. According to some embodiments, the trigger delay calibration procedure can include, for each RU measurement mode (e.g., current or voltage measurement modes), performing a series of pulse delay measurements. Then, the user can, after configuring the marker delay to the corresponding trigger delay value, calculate the trigger delay by taking the average of the pulse delay measurements rounded to the nearest trigger clock period, according to some embodiments. According to some embodiments, an example algorithm to measure trigger delay can be characterized by the following code block or script:

```
  Measurement modes = [PGU, FIV]
  for (each measurement mode) do
    for (i < n) do
      pulseDelays[i] = measure pulse delay
    end
    triggerDelays[measurementMode] = round( avg( pulseDelays ) / trigger
clock period )
  end
```

Furthermore, the trigger delay range can be characterized by the formula Trigger Delay Range=[0 . . . maxMarkerDelay].

According to some embodiments, the trigger delay calibration procedure can use particular settings for the remote head or RU. For example, a “PGU—Monitor voltage” remote head measurement mode, there can possibly not be a calibration load, the FGEN gain can be set to 6.0V, and the pulse amplitude at the oscilloscope input can be set to +/−500 mV, according to some embodiments. Alternatively, for a “Fast I/V—Measure voltage 10 mA” remote head measurement mode, there can possibly not be a calibration load, the FGEN gain can be set to 2.5V, and the pulse amplitude at the oscilloscope input can be set to +/−500 mV, according to some embodiments. In other embodiments, for a “Fast I/V—Measure voltage 10 mA*” remote head measurement mode, there can possibly not be a calibration load, the FGEN gain can be set to 1.25V, and the pulse amplitude at the oscilloscope input can be set to +/−250 mV. As another alternative, for a “Fast I/V—Monitor voltage 10 mA” remote head measurement mode, there can possibly not be a calibration load, the FGEN gain can be set to 2.5V, and the pulse amplitude at the oscilloscope input can be set to +/−500 mV, according to some embodiments. In other embodiments, for a “Fast I/V—Measure Current 10 mA” remote head measurement mode, there can be a 1k Ohm calibration load, the FGEN gain can be set to 2.5V, and the pulse amplitude at the oscilloscope input can be set to +/−500 mV.

In some embodiments, for a “Measure Current” mode, the 100 uA, 10 uA, and 1 uA current ranges can be designed for direct current (DC) measurements. Accordingly, it is possible that the slew rate of the remote head response will not track the slew rate of the stimulus signal. Therefore, while it can be possible to measure pulse delay in the 1 mA mode, it can be more efficient to use calculated (e.g., expected) delays relative to the measured 10 mA delay value, according to some embodiments. Accordingly, these calculated delays can be written to a trigger delay look up table (LUT) and the appropriate 10 mA delay value can used be for the other current ranges and until delay offsets are provided, according to some embodiments.

Additionally, for the “Monitor/Measure Voltage” modes, the delay can be expected to be the same across all current ranges, according to some embodiments. Therefore, it can be possible to use the delay value measured in the 10 mA range when populating the trigger delay LUT values for the 1 mA, 100 uA, 10 uA, and 1 uA ranges, according to some embodiments.

Furthermore, it can be beneficial to consider compensating for an instrument driver (e.g., such as FGEN) and its associated analog path delay, according to some embodiments. For example, an AWG analog front end can have a low and high gain path, according to some embodiments. The high gain path can be enabled when the configured gain value exceeds 1.375V (assuming a 50 Ohm load impedance) and otherwise the low gain path is enabled. The propagation delays of these paths can possibly not be matched and therefore it can be beneficial to measure and compensate for the difference in delay between these paths to maintain trigger-to-output alignment across all supported gain values, according to some embodiments.

According to aforementioned trigger settings, two delay measurements can be made in the “Measure Voltage” mode, according to some embodiments. More specifically, the first delay measurement can be associated with the high gain path enabled (2.5V gain) and the second delay measurement can be associated with the low gain path enabled (1.25V gain). In some embodiments, the low gain measurement can be used to calculate the high gain analog path delay offset according to the following formula:

$$High gain path delay offset = high gain delay - low gain delay$$

Accordingly, when the low gain path is enabled, the user can subtract the high gain path delay offset from the measured trigger delay value for the desired remote head mode, according to some embodiments. Alternatively, the user can use the measured trigger delay value as-is and apply it at the AWG, according to some embodiments.

According to some embodiments, the trigger delay LUT values can need to be recalculated and repopulated if the configured gain requires the analog front end to switch between the high or low gain paths. Additionally and after the gain has been configured, it can be beneficial to determine which gain path is enabled (e.g., via an attribute such as NIFGEN_ATTR_ANALOG_PATH as one example).

Furthermore, it can be beneficial to consider calibration constants when performing trigger calibration procedures, according to some embodiments. For example, when storing trigger calibration values in non-volatile memory, it can be useful to store the measured value (before rounding) with the highest possible precision. In doing so, this can provide the option to compensate for residual delays in the future. For example, trigger calibration values such as trigger timing constants, PGU delays, Fast I/V—Measure Voltage Delay, Fast I/V—Monitor Voltage Delay, Fast I/V Measure Current Delay (10 mA), and High Gain Analog Path Delay Offset can all be stored as a measured value, according to some embodiments. Alternatively, trigger calibration values such as Fast I/V Measure Current Delay (1 mA), Fast I/V Measure Current Delay (100 μA), Fast I/V Measure Current Delay (10 μA), and Fast I/V Measure Current Delay (10 μA) can all be stored values corresponding to a 10 mA delay plus a calculated offset, according to some embodiments.

Moreover, the pulse and triggering waveforms described herein can be characterized by various periodic waveforms including (but not limited to) square, sawtooth, ramp, pulse, triangle and sinusoidal pulse waveforms, according to some embodiments.

Furthermore and according to other embodiments, these calibration procedures are not limited to voltage or current measurements and could be utilized for measuring other quantities. For example, these calibration procedures could be utilized for measuring power with a power detector or light intensity with a light detector, according to some embodiments.

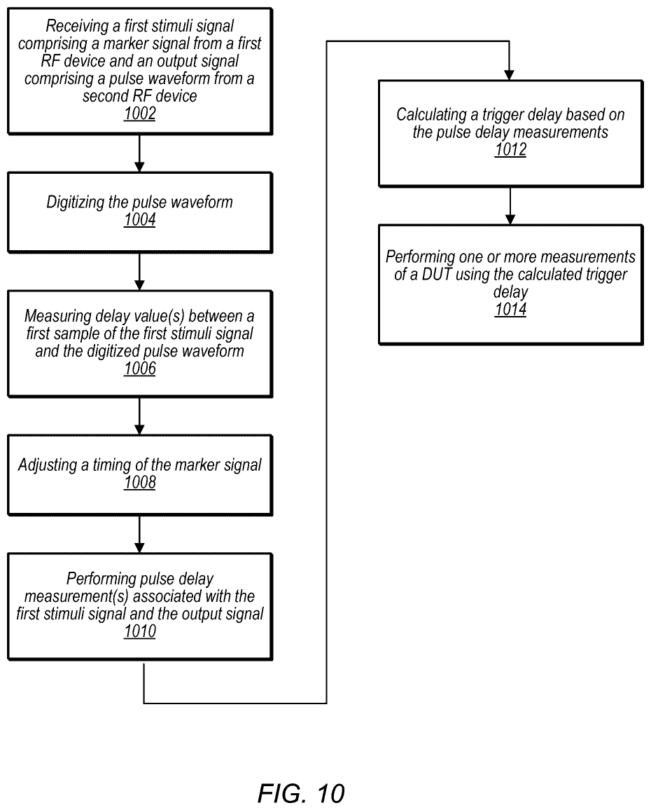

### FIG. 10—Method of Synchronization of RF Devices for Sample Accurate Waveform Measurements

FIG. 10 is a flow diagram illustrating an example method of synchronization of RF Devices for Sample Accurate Waveform Measurements, according to some embodiments. For example, FIG. 10 describes aspects of the trigger calibration procedure and trigger timing and delay calibration procedures illustrated in FIGS. 8-9, according to some embodiments.

Aspects of the method of FIG. 10 can be implemented at least in part by synchronization system 100 including a computer, such as the computer 102, in communication with a network as illustrated in and described with respect to the Figures, or more generally in conjunction with any of the computer systems or devices shown in the Figures, among other circuitry, systems, devices, elements, or components shown in the Figures, among other devices, as desired. For example, processing unit 210, a system memory 212, and/or storage device(s) 215 and/or other communication circuitry included in the Figures (among various possibilities) can cause the computer 102 to perform some or all of the illustrated method elements. Note that while at least some elements of the method are described in a manner relating to the use of pulse measurement synchronization techniques, such description is not intended to be limiting to the disclosure, and aspects of the method can be used in any telecommunications system, as desired. In various embodiments, some of the elements of the methods shown can be performed concurrently, in a different order than shown, can be substituted for by other method elements, or can be omitted. Additional method elements can also be performed as desired. For example, the method of FIG. 10 may be used in conjunction with, or utilize any of the aspects or elements of, any of the previously discussed Figures, according to some embodiments. As shown, the method can operate as follows.

At 1002, the method can include receiving, a first stimuli signal comprising a maker signal from a first RF device and an output signal from a second RF device, wherein the output signal is based at least in part on a second stimuli signal comprising a pulse waveform transmitted from the first RF device to the second RF device, according to some embodiments. According to some embodiments, the first RF device can be a signal generator, the second RF device can be a remote unit (RU). Additionally or alternatively, the second stimuli signal can be associated with an analog signal path delay and the first stimuli signal can be associated with a digital trigger path delay. In some embodiments, the second RF device can be communicatively coupled to the DUT and the output signal can be based at least in part on the DUT's response to the first stimuli signal.

At 1004, the method can include digitizing, at the third RF device, the output signal, according to some embodiments. For example, the third RF device can utilize an analog to digital converter as part of digitizing the output signal, according to some embodiments.

At 1006, the method can include measuring one or more delay values between a first sample of the first stimuli signal and the digitized pulse waveform, according to some embodiments. According to some embodiments, said measuring the one or more delay values can include sweeping a marker delay in increments while measuring delays between the first sample of the first stimuli signal and the digitized pulse waveform.

At 1008, the method can include adjusting a timing of the marker signal, according to some embodiments. In some embodiments, when the measured delays decrease by a trigger clock period, said adjusting can include adjusting the timing of the marker signal by half of the trigger clock period.

At 1010, the method can include performing one or more pulse delay measurements associated with the first stimuli signal and the output signal, according to some embodiments. According to further embodiments, said performing the one or more pulse delay measurements can be according to one or more measurement modes of the second RF device including a voltage measurement mode or a current measurement mode.

At 1012, the method can include calculating a trigger delay, according to some embodiments. In some embodiments, said calculating can include calculating an average of the one or more pulse delay measurements and rounding the average to the nearest trigger clock period.

At 1014, the method can include performing, using the calculated trigger delay, one or more measurements of a device under test (DUT), according to some embodiments. For example, the user and/or computer 102 via software can be able to implement the calculated trigger delay at the signal generator 108 in order to perform additional sample level accurate pulse measurements, according to some embodiments.

The presently disclosed embodiments can be realized in any of various forms. For example, any of the various embodiments can be realized as a computer-implemented method, a computer-readable memory medium, or a computer system. Furthermore, any of the presently disclosed embodiments can be realized using one or more custom-designed hardware devices such as ASICs and/or using one or more programmable hardware elements such as FPGAs.

While some of the Figures describe particular parameter settings or values related to systems and methods for sample accurate waveform measurement synchronization, other values and/or other possible parameters may be used in different scenarios and/or setups, according to some embodiments.

### EXAMPLE EMBODIMENTS

In some embodiments, a method for synchronizing radio frequency (RF) devices can include receiving, a first stimuli signal including a maker signal from a first RF device and an output signal from a second RF device, wherein the output signal can be based at least in part on a second stimuli signal including a pulse waveform transmitted from the first RF device to the second RF device. The method can include digitizing the pulse waveform, measuring delay values between a first sample of the first stimuli signal and the digitized pulse waveform, and adjusting a timing of the marker signal. The method can include performing one or more pulse delay measurements associated with the first stimuli signal and the output signal as well as calculating a trigger delay. The method can also include performing, using the trigger delay, one or more measurements associated with a device under test (DUT).

According to some embodiments, measuring the one or more delay values can include sweeping a marker delay in increments while measuring delays between the first sample of the first stimuli signal and the digitized pulse waveform. Additionally or alternatively, when the delays decrease by a trigger clock period, said adjusting can include adjusting the timing by half of the trigger clock period. In some embodiments, said calculating can include calculating an average of the one or more pulse delay measurements and rounding the average to the nearest trigger clock period.

According to further embodiments, said performing can be according to one or more measurement modes of the second RF device including a voltage measurement mode or a current measurement mode. In some embodiments, the second RF device can be communicatively coupled to the DUT and the output signal can be based at least in part on the DUT's response to the first stimuli signal. Additionally or alternatively, the second stimuli signal can be associated with an analog signal path delay and the first stimuli signal can be associated with a digital trigger path delay.

In some embodiments, a method for synchronizing radio frequency (RF) devices can include transmitting, from a first RF device, a first stimuli signal comprising a pulsed waveform to a second RF device and a second stimuli signal comprising a marker signal to a third RF device. The method can further include receiving, at the third RF device, the second stimuli signal and an output signal from the second RF device. The method can include digitizing the pulse waveform, measuring delay values between a first sample of the second stimuli signal and the digitized pulse waveform, and adjusting a timing of the marker signal. The method can include performing one or more pulse delay measurements associated with the second stimuli signal and the output signal as well as calculating and applying a trigger delay at the first RF device.

According to some embodiments, the one or more delay values can be measured by sweeping a marker delay in small increments while measuring delays between the first sample of the second stimuli signal and the digitized pulse waveform. Additionally or alternatively, when the delays decrease by a trigger clock period, the timing of the marker signal can be adjusted by half of the trigger clock period of the third RF device. In some embodiments, the trigger delay can be calculated based at least in part on calculating an average of the one or more pulse delay measurements and rounding the average to the nearest trigger clock period.

According to further embodiments, performing the one or more pulse delay measurements can be according to one or more measurement modes of the second RF device including a voltage measurement mode or a current measurement mode. In some embodiments, the second RF device can be communicatively coupled to a device under test (DUT) and the output signal can be based at least in part on the DUT's response to the first stimuli signal. According to some embodiments, the first RF device can be a signal generator, the second RF device can be a remote unit (RU), and the third RF device can be an oscilloscope. Additionally or alternatively, the first stimuli signal can be associated with an analog signal path delay and the second stimuli signal can be associated with a digital trigger path delay.

In some embodiments, a system for synchronizing radio frequency (RF) devices can include a signal generator, a remote unit (RU) communicatively coupled to a device under test (DUT), and an oscilloscope. Furthermore, the system can be configured to input, from the signal generator, a first input stimuli signal into the RU wherein the first stimuli signal comprises a pulsed waveform and input, from the signal generator, a second input stimuli signal into the oscilloscope. Furthermore, the system can be configured to receive, at the oscilloscope, the second input stimuli signal from the signal generator and an output signal from the RU. In some embodiments, the output signal can be based at least in part on the first input stimuli signal. Additionally, the system can be configured to, at the oscilloscope, digitize the pulse waveform and measure one or more delay values between a first sample of the second input stimuli signal and the digitized pulse waveform. Furthermore, the system can be configured to adjust, based at least in part on the one or more delay values, a timing of the marker signal and perform one or more pulse delay measurements associated with the second input stimuli signal from the signal generator and the output signal from the RU. According to further embodiments, the system can be configured to calculate, based on the one or more pulse delay measurements, a trigger delay for the signal generator and apply, at the signal generator, the trigger delay.

In some embodiments, a non-transitory computer-readable storage medium can store program instructions which, when executed by a computer, are configured to operate a calibration system to synchronize radio frequency (RF) devices. Additionally or alternatively, the calibration system can include the computer as well as first, second, and third RF devices, and said operating can include transmitting, from the first RF device, a first stimuli signal to the second RF device. According to some embodiments, the first stimuli signal can include a pulsed waveform and said operating can further include transmitting, from the first RF device, a second stimuli signal comprising a marker signal to a third RF device. Additionally, said operating can include receiving, at the third RF device, the second stimuli signal from the first RF device and an output signal from the second RF device. Additionally or alternatively, the output signal can be based at least in part on the first stimuli signal. Furthermore, said operating can include, at the third RF device, digitizing the pulse waveform and measuring one or more delay values between a first sample of the second stimuli signal and the digitized pulse waveform. In some embodiments, said operating can include adjusting, based at least in part on the one or more delay values, a timing of the marker signal and performing one or more pulse delay measurements associated with the second stimuli signal from the first RF device and the output signal from the second RF device. According to further embodiments, said operating can include calculating, based on the one or more pulse delay measurements, a trigger delay and applying, at the first RF device, the trigger delay.

A computer-readable memory medium is a memory medium that stores program instructions and/or data, where the program instructions, if executed by a computer system, cause the computer system to perform a method, e.g., any of a method embodiments described herein, or, any combination of the method embodiments described herein, or, any subset of any of the method embodiments described herein, or, any combination of such subsets.

In some embodiments, a computer system can be configured to include a processor (or a set of processors) and a memory medium. The memory medium stores program instructions. The processor is configured to read and execute the program instructions from the memory medium. The program instructions are executable by the processor to implement a method, e.g., any of the various method embodiments described herein (or, any combination of the method embodiments described herein, or, any subset of any of the method embodiments described herein, or, any combination of such subsets). The computer system can be realized in any of various forms. For example, the computer system can be a personal computer (in any of its various realizations), a workstation, a computer on a card, an application-specific computer in a box, a server computer, a client computer, a hand-held device, a mobile computing device, a tablet computer, a wearable computer, etc.

In some embodiments, a set of computers distributed across a network can be configured to partition the effort of executing a computational method (e.g., any of the method embodiments disclosed herein).

Although the embodiments above have been described in considerable detail, numerous variations and modifications will become apparent to those skilled in the art once the above disclosure is fully appreciated. It is intended that the following claims be interpreted to embrace all such variations and modifications.

We claim:

1. A method for synchronizing radio frequency (RF) devices, comprising:
receiving, a first stimuli signal comprising a maker signal from a first RF device and an output signal from a second RF device, wherein the output signal is based at least in part on a second stimuli signal comprising a pulse waveform transmitted from the first RF device to the second RF device;
digitizing the pulse waveform;
measuring one or more delay values between a first sample of the first stimuli signal and the digitized pulse waveform;
adjusting, based at least in part on the one or more delay values, a timing of the marker signal;
performing one or more pulse delay measurements associated with the first stimuli signal and the output signal from the second RF device;
calculating, based on the one or more pulse delay measurements, a trigger delay; and
performing, using the trigger delay, one or more measurements associated with a device under test (DUT).

2. The method of claim 1, said measuring the one or more delay values comprises:
sweeping a marker delay in increments while measuring delays between the first sample of the first stimuli signal and the digitized pulse waveform.

3. The method of claim 2, wherein when the measured delays decrease by a trigger clock period, said adjusting comprises:
adjusting the timing of the marker signal by half of the trigger clock period.

4. The method of claim 1, said calculating comprises:
calculating an average of the one or more pulse delay measurements and rounding the average to the nearest trigger clock period.

5. The method of claim 1, wherein said performing is according to one or more measurement modes of the second RF device, and wherein the one or more measurement modes comprise at least one of:
a voltage measurement mode; or
a current measurement mode.

6. The method of claim 1, wherein the second RF device is communicatively coupled to the DUT and wherein the output signal is based at least in part on the DUT's response to the second stimuli signal.

7. The method of claim 1, wherein the second stimuli signal is associated with an analog signal path delay and the first stimuli signal is associated with a digital trigger path delay.

8. A system for synchronizing radio frequency (RF) devices, the system comprising:
a signal generator;
a remote unit (RU) communicatively coupled to a device under test (DUT); and
an oscilloscope, wherein the system is configured to:
input, from the signal generator, a first input stimuli signal into the RU wherein the first stimuli signal comprises a pulsed waveform;
input, from the signal generator, a second input stimuli signal into the oscilloscope;
receive, at the oscilloscope, the second input stimuli signal from the signal generator and an output signal from the RU, wherein the output signal is based at least in part on the first input stimuli signal;
digitize, at the oscilloscope, the pulse waveform;
measure, at the oscilloscope, one or more delay values between a first sample of the second input stimuli signal and the digitized pulse waveform;
adjust, based at least in part on the one or more delay values, a timing of the marker signal;
perform one or more pulse delay measurements associated with the second input stimuli signal from the signal generator and the output signal from the RU;
calculate, based on the one or more pulse delay measurements, a trigger delay for the signal generator; and
apply, at the signal generator, the trigger delay.

9. The system of claim 8, wherein the one or more delay values are measured by sweeping a marker delay in small increments while measuring delays between the first sample of the second stimuli signal and the digitized pulse waveform, wherein when the delays decrease by a trigger clock period, the timing of the marker signal is adjusted by half of the trigger clock period of the oscilloscope.

10. The system of claim 8, wherein the trigger delay is calculated based at least in part on calculating an average of the one or more pulse delay measurements and rounding the average to the nearest trigger clock period of the oscilloscope.

11. The system of claim 8, wherein performing the one or more pulse delay measurements is according to one or more measurement modes of the RU, and wherein the one or more measurement modes comprise at least one of:
a voltage measurement mode; or
a current measurement mode.

12. The system of claim 8, wherein the first input stimuli signal is associated with an analog signal path delay and the second input stimuli signal is associated with a digital trigger path delay.

13. The system of claim 8, wherein the output signal is based at least in part on the DUT's response to the first input stimuli signal.

14. A non-transitory computer-readable storage medium storing program instructions which, when executed by a computer, are configured to operate a calibration system to synchronize radio frequency (RF) devices, wherein the calibration system comprises the computer, and first, second, and third RF devices, and wherein said operating comprises:
transmitting, from a first RF device, a first stimuli signal to a second RF device, wherein the first stimuli signal comprises a pulsed waveform;
transmitting, from the first RF device, a second stimuli signal comprising a marker signal to a third RF device;
receiving, at the third RF device, the second stimuli signal from the first RF device and an output signal from the second RF device, wherein the output signal is based at least in part on the first stimuli signal;
digitizing, at the third RF device, the pulse waveform;
measuring, at the third RF device, one or more delay values between a first sample of the second stimuli signal and the digitized pulse waveform;
adjusting, based at least in part on the one or more delay values, a timing of the marker signal;
performing one or more pulse delay measurements associated with the second stimuli signal from the first RF device and the output signal from the second RF device;
calculating, based on the one or more pulse delay measurements, a trigger delay; and
applying, at the first RF device, the trigger delay.

15. The non-transitory computer-readable storage medium of claim 14, wherein the one or more delay values are measured by sweeping a marker delay in small increments while measuring delays between the first sample of the second stimuli signal and the digitized pulse waveform, wherein when the delays decrease by a trigger clock period, the timing of the marker signal is adjusted by half of the trigger clock period of the third RF device.

16. The non-transitory computer-readable storage medium of claim 14, wherein the trigger delay is calculated based at least in part on calculating an average of the one or more pulse delay measurements and rounding the average to the nearest trigger clock period.

17. The non-transitory computer-readable storage medium of claim 14, wherein performing the one or more pulse delay measurements is according to one or more measurement modes of the second RF device, and wherein the one or more measurement modes comprise at least one of:
a voltage measurement mode; or
a current measurement mode.

18. The non-transitory computer-readable storage medium of claim 14, wherein the second RF device is communicatively coupled to a device under test (DUT), and wherein the output signal is based at least in part on the DUT's response to the first stimuli signal.

19. The non-transitory computer-readable storage medium of claim 14, wherein:
the first RF device is a signal generator;
the second RF device is a remote unit (RU); and
the third RF device is an oscilloscope.

20. The non-transitory computer-readable storage medium of claim 14, wherein the first stimuli signal is associated with an analog signal path delay and the second stimuli signal is associated with a digital trigger path delay.
